(19) United States
(12) Patent Application Publication
(10) Pub. No.: US 2015/0255586 A1
(43) Pub. Date: Sep. 10, 2015

(54) SEMICONDUCTOR DEVICE

(71) Applicant: KABUSHIKI KAISHA TOSHIBA, Tokyo (JP)

(72) Inventor: Tatsuo NAIJO, Hakusan Ishikawa (JP)

(21) Appl. No.: 14/474,048

(22) Filed: Aug. 29, 2014

(30) Foreign Application Priority Data
Mar. 4, 2014 (JP) 2014-041467

(51) Int. Cl. H01L 29/739; H01L 29/66

(52) U.S. Cl. CPC H01L 29/7395; H01L 29/66348

(57) ABSTRACT

According to one embodiment, a semiconductor device includes an optional first electrode, a second electrode, a first and a third semiconductor region of a first conductivity type, a second semiconductor region of a second conductivity type, a third electrode, and a second insulating film. The first semiconductor region extends between the first electrode and the second electrode. The second semiconductor region extends between the first semiconductor region and the second electrode. The third semiconductor region extends between the second semiconductor region and the second electrode. The third semiconductor region has a dopant concentration higher than a dopant concentration of the first semiconductor region. The third electrode is in contact, via a first insulating film, with the first semiconductor region, the second semiconductor region, and the third semiconductor region. The third semiconductor region is disposed between the second insulating film and the third electrode.

### CROSS-REFERENCE TO RELATED APPLICATION

This application is based upon and claims the benefit of priority from Japanese Patent Application No. 2014-041467, filed Mar. 4, 2014, the entire contents of which are incorporated herein by reference.

### FIELD

Embodiments described herein relate generally to a semiconductor device.

### BACKGROUND

Inverter circuits used to convert direct current to alternating current to drive a motor may encounter a short circuit load, or they may experience false ON events due to noise in the gate signal. When a false ON event occurs, the gate signal will switch to the ON state, and the power supply voltage is directly applied to the transistor element. A short circuit load can occur as a result of a load device failure, or incorrect wiring of the load to the semiconductor device, etc. The withstand capability that the element demonstrate in this state is referred to as, for example, short-circuit withstand capability (Esc). In addition, the current flowing in the element at this moment is referred to as, for example, short-circuit current. To prevent device failure, the inverter circuit must be switched to an off state when a short circuit is encountered.

In the semiconductor devices in the related art such as MOSFET (Metal Oxide Semiconductor Field Effect Transistor) and IGBT (Insulated Gate Bipolar Transistor), the short-circuit current is set small to obtain a certain degree of short-circuit withstand capability, i.e., the semiconductor device can encounter a short circuit for a period of time known as the withstand time, the time varying in part based on the voltage applied thereto and current which may flow when a short circuit is encountered. One mechanism for limiting saturation current of the device is to reduce the width of the channel in the source region (emitter region) to reduce the saturation current value if a short circuit load is encountered. However, this measure narrows the channel width of the semiconductor device, thereby causing larger resistance and resultant heat generation and power loss, and greater power loss in the semiconductor device, when in the “on-state”.

### DESCRIPTION OF THE DRAWINGS

FIG. 1A is a schematic cross-sectional view illustrating a semiconductor device according to a first embodiment, and FIG. 1B is a schematic plan view illustrating the semiconductor device according to the first embodiment.

FIGS. 2A to 2C are schematic cross-sectional views illustrating a production process of the semiconductor device according to the first embodiment.

FIGS. 3A and 3B are schematic cross-sectional views illustrating behavior of the semiconductor device according to the first embodiment.

FIG. 4 is a diagram illustrating a relationship between a collector to emitter voltage (Vce) and a collector to emitter current (Ic) according to the first embodiment and a comparative example.

FIG. 5 is a schematic cross-sectional view illustrating a semiconductor device according to a second embodiment.

FIGS. 6A and 6B are schematic cross-sectional views illustrating semiconductor devices according to a third embodiment.

FIGS. 7A and 7B are schematic cross-sectional views illustrating semiconductor devices according to a fourth embodiment.

### DETAILED DESCRIPTION

A semiconductor device having enhanced withstand characteristic is provided.

In general, according to one embodiment, a semiconductor device includes an optional first electrode, a second electrode, a first semiconductor region of a first conductivity type, a second semiconductor region of a second conductivity type, a third semiconductor region of the first conductivity type, a third electrode, and a second insulating film. The first semiconductor region is provided between the first electrode and the second electrode. The second semiconductor region is provided between the first semiconductor region and the second electrode. The third semiconductor region is provided between the second semiconductor region and the second electrode. The third semiconductor region is of a dopant concentration higher than a dopant concentration of the first semiconductor region, and is in contact with the second electrode. The third electrode is in contact, via a first insulating film, with the first semiconductor region, the second semiconductor region, and the third semiconductor region. The second insulating film interposes the third semiconductor region in cooperation with the third electrode.

Hereinafter, embodiments will be described with reference to drawings. In the following description, the same reference symbols are given to the same members, and description once made for a member will not be repeated as appropriate.

### First Embodiment

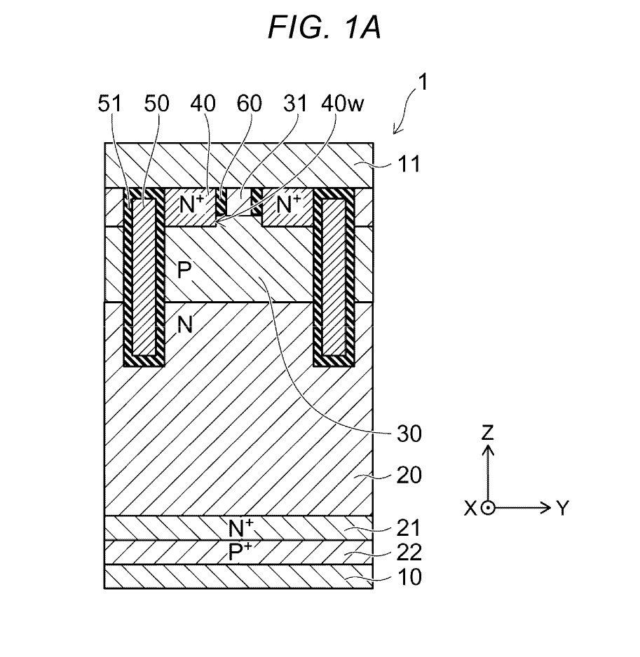

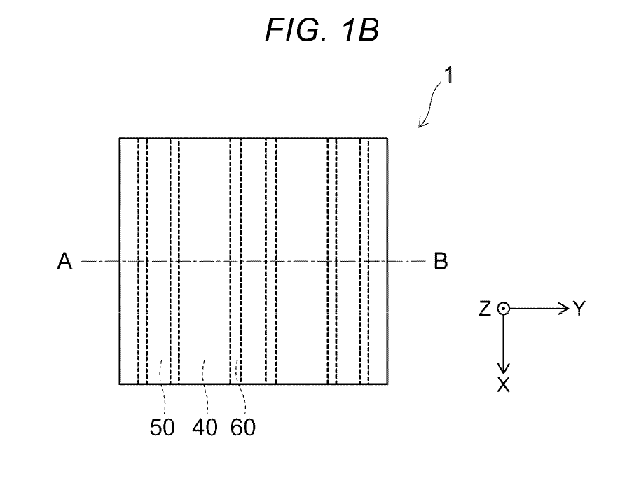

FIG. 1A is a schematic cross-sectional view illustrating a semiconductor device according to the first embodiment, and FIG. 1B is a schematic plan view illustrating the semiconductor device according to the first embodiment.

FIG. 1A illustrates a cross-section taken along line A-B in FIG. 1B.

The semiconductor device 1 is an IGBT of a top and bottom electrode structure.

In the semiconductor device 1, an n-type drift region 20 (first semiconductor region) is provided between a collector electrode 10 (first electrode) and an emitter electrode 11 (second electrode). A p-type base region 30 (second semiconductor region) is provided between the drift region 20 and an emitter electrode 11.

An n⁺-type emitter region 40 (third semiconductor region) is provided between the base region 30 and the emitter electrode 11. The dopant concentration of the emitter region 40 is higher than the dopant concentration of the drift region 20. For example, the dopant concentration in the emitter region 40 is 1×10¹⁸ (atoms/cm³) or more. The emitter region 40 is in contact with the emitter electrode 11.

A gate electrode 50 (third electrode) is electrically connected, via a gate insulating film 51 (first insulating film), with the drift region 20, the base region 30, and the emitter region 40. Although the gate electrode 50 has a trench gate structure, the gate electrode 50 may have a planar structure.

In addition, the semiconductor device 1 includes an insulating film 60 (second insulating film) which is in contact with the emitter region 40. For example, the insulating film 60 is in contact with a side portion 40w of the emitter region 40 on a side thereof opposed to the surface of the emitter region in contact with the gate insulator film 51. It is noted that, since the side portion 40w is opposite to the gate insulating film 51 across the emitter region 40, the emitter region 40 has a structure interposed by the gate electrode 50 (and insulating film 51) and the insulating film 60. The insulating film 60 is also in contact with the base region 30, i.e., it extends from a contact position with the emitter electrode 11 to the base region 30. The distance between the lower surface of the insulating film 60 contacting the base region and the collector electrode 10 is longer than the distance between the lowermost surface of the emitter region 40 contacting the base region 30 and the collector electrode 10. In other words, the lowermost surface of the insulating film 60 is shallower than the lowermost surface of the emitter region 40. The thickness of the insulating film 60 in the Y direction is, for example, 100 nm or less. In addition, a p⁺-type contact region 31 is provided on the base region 30. The p⁺-type contact region 31 is adjacent to the insulating film 60.

Between the collector electrode 10 and the drift region 20, a p⁺-type collector region 22 (fourth semiconductor region) is provided. The p type dopant concentration of the collector region 22 is higher than the p type dopant concentration of the base region 30. In addition, between the collector region 22 and the drift region 20, an n⁺-type buffer region 21 is provided. The n type dopant concentration of the buffer region 21 is higher than the n type dopant concentration of the drift region 20.

It is noted that, the p⁺-type collector region 22 may be removed as appropriate to make the semiconductor device 1 a MOSFET. When the semiconductor device 1 is a MOSFET, “collector” is alternatively read as “drain”, and “emitter” is alternatively read as “source”.

Further, the collector region 22, the buffer region 21, the drift region 20, the base region 30, the emitter region 40, and the contact region 31 may be configured of, for example, silicon (Si). Aside from silicon (Si), these components of the device may be configured of silicon carbide (SiC), gallium nitride (GaN) or the like.

The material of the collector electrode 10 and the emitter electrode 11 can be, for example, a metal including at least one selected from the group including aluminum (Al), titanium (Ti), nickel (Ni), tungsten (W), gold (Au) and the like.

The gate electrode 50 includes polysilicon, metal or the like doped with dopant elements. Further, in the embodiment, the insulating film is, for example, an insulating film including silicon oxide (SiOₓ), silicon nitride (SiNₓ) or the like.

Further, in the embodiment, n-type and n⁺-type may be considered as a first conductivity type. In addition, the designations n-type and n⁺-type mean that the dopant atom concentration increases in this order. As dopant elements of the first conductivity type, phosphorus (P), arsenic (As), or the like may be employed, for example. The representation of p-type and p⁺-type may be considered as a second conductivity type. In addition, designations p-type and p⁺-type mean that the dopant atom concentration increases in this order. As dopant elements of the second conductivity type, boron (B) or the like may be employed, for example. In the present embodiment, n-type is the first conductivity type and p-type is the second conductivity type, but p-type may be the first conductivity type and n-type may be the second conductivity type.

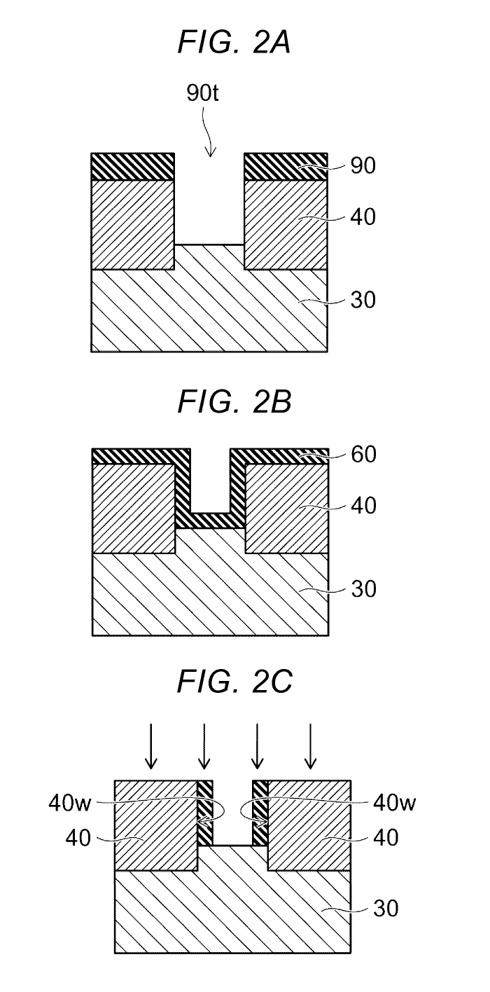

FIGS. 2A to 2C are schematic cross-sectional views illustrating a production process of the semiconductor device according to the first embodiment.

FIGS. 2A to 2C illustrate the production process for forming the insulating film 60. Also, FIGS. 2A to 2C illustrate an enlarged view of the base region 30 and the emitter regions 40.

First, as illustrated in FIG. 2A, a mask layer 90 was formed on the base region 30 and the mask layer 90 was patterned to form openings therethrough and the base region 30, uncovered by the opening in the mask layer 90, is etched by RIE (Reactive Ion Etching) to form a trench 90t extending through the layer to form the emitter region 40 to the base region 30.

Thereafter, as illustrated in FIG. 2B, the insulating film 60 is formed on the inner walls of the trench 90t and on the base region 30 by a CVD (Chemical Vapor Deposition) process.

Thereafter, as illustrated in FIG. 2C, a portion of the insulating film 60 at the base of the trench is removed by RIE (reactive ion etch). Here, in FIG. 2C, an example of the etchant direction of RIE is indicated by arrows. The insulating film 60 formed in the step of FIG. 2B is etched preferentially in the area facing against the arrows, i.e., from the base of the trench. Thereby, the insulating film 60 that is in contact with the side portions 40w of the emitter regions 40 remains. By a production process like this, insulating films 60 which are in contact with the side portions 40w of the emitter regions 40 are formed.

The behavior of the semiconductor device 1 will be described.

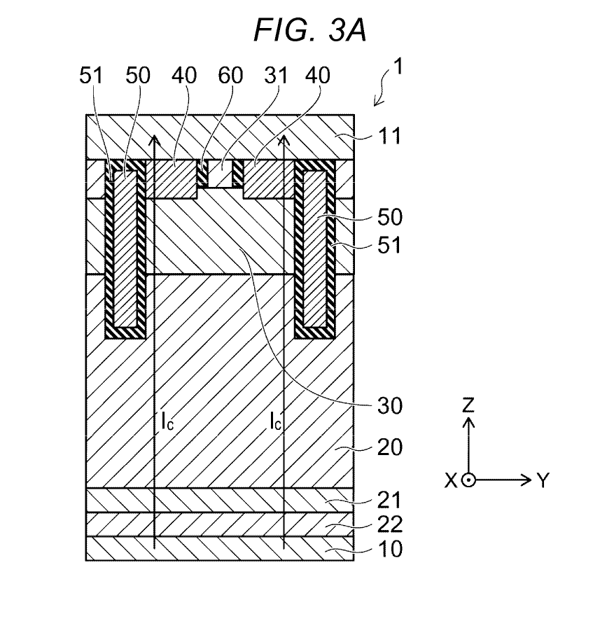

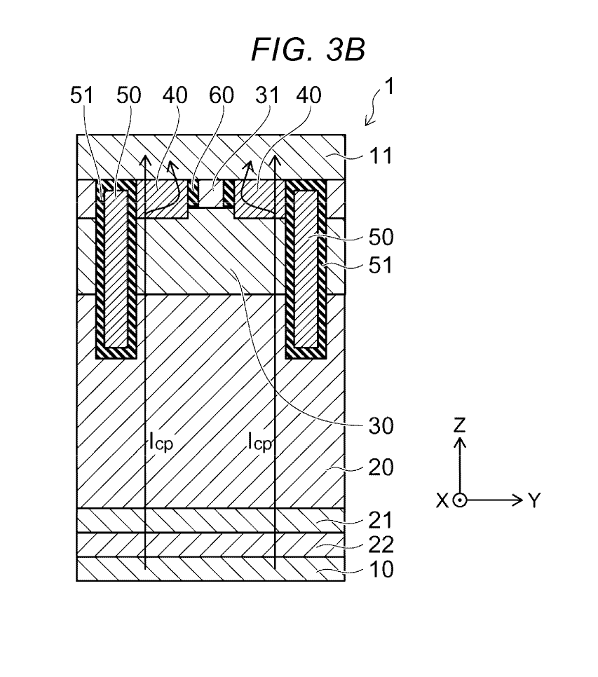

FIGS. 3A and 3B are schematic cross-sectional views illustrating the behavior of the semiconductor device according to the first embodiment.

Here, FIG. 3A illustrates the behavior of the semiconductor device 1 when used within the device current rating, and FIG. 3B illustrates the behavior of the semiconductor device 1 in which saturation current flows.

As illustrated in FIG. 3A, when a potential that is higher than the potential of the emitter electrode 11 is applied on the collector electrode 10, the potential of the gate electrode 50 is raised to a threshold voltage (Vth) or more. Thereby, in the base region 30, an inversion layer (channel region) is formed along (adjacent to) the gate insulating film 51. As a result, current Ic flows from the collector electrode 10 toward the emitter electrode 11.

The current that flows within the device rating is smaller than the saturation current, the effect of which on the device 1 is illustrated in FIG. 3A. Therefore, the current that reaches the emitter region 40 from the collector region 22 side passes through the emitter region 40 and is promptly discharged to the emitter electrode 11. Within the rating, even if the insulating film 60 is provided beside the emitter region 40, the on-state resistance is not increased.

Next, description will be made of the effect on the device 1 in the situation where the collector to emitter voltage is higher than the state of FIG. 3A and saturation current Icp flows between the collector and the emitter.

In this case, the current flowing between the collector region 22 and the emitter 11 is larger than the current flowing in the device 1 as described with respect to FIG. 3A. Accordingly, as illustrated in FIG. 3B, the current that reaches the emitter region 40 from the collector side is more likely to diffuse in the emitter region 40. Here, because the insulating film 60 is provided on the side portion 40w of the emitter region 40, the saturation current Icp is more likely to accumulate and pass through the emitter region 40 as a result of the shielding effect of the insulating film 60, where the insulating film 60 prevents the current from flowing into the contact region from the emitter region 40.

Thereby, the potential of the emitter region 40 increases, and the potential of the base region 30 which is in contact with the emitter region 40 is induced to increase by the increase of the potential of the emitter region. As a result, the apparent potential of the gate electrode 50 falls. Accordingly, the width of the channel region is narrowed to reduce the saturation current flow. That is, in the semiconductor device 1, the saturation current is reduced appropriately to prevent excessive flow of the saturation current which might result during a short circuit event.

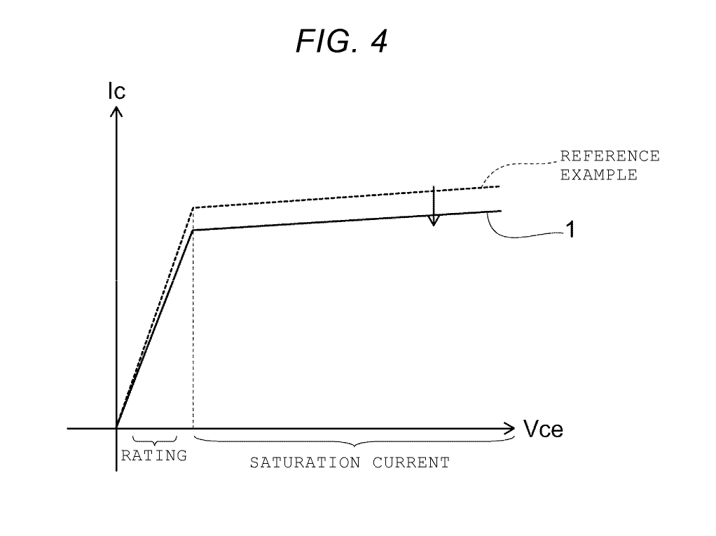

FIG. 4 is a diagram illustrating a relationship between the collector to emitter voltage (Vce) and the collector to emitter current (Ic) according to the first embodiment.

FIG. 4 illustrates Vce-Ic curves of the semiconductor device 1 and of a reference example that removed the insulating film 60 from the semiconductor device 1 and hence the channel may easily expand into the contact region 31. As shown in FIG. 4, the current flowing in a saturation current condition is lower in the embodiment than in the reference example.

Inverter circuits used in driving a motor or the like sometimes suffer from load short circuit, or perform false ON behavior or the like due to noise in the gate signal. In such cases, when the gate signal is in an ON state, the power supply voltage is sometimes directly applied on the transistor (for example, IGBT). In anticipation of such cases, the device is configured to have short-circuit withstand capability (Esc).

As methods to maintain high short-circuit withstand capability, there is a method to set a small maximum current value flowing during the element short circuit (short-circuit current: Isc), or a method to prolong the time until destruction (short circuit duration: Tsc). By employing one of these methods, a margin is secured with respect to the shutoff timing of an external protection circuit.

Here, the short-circuit current is dependent on the saturation current (Icp) of the transistor in ON state. That is, if the saturation current is reduced, the short circuit duration may be prolonged. This is, when a short circuit is encountered by the semiconductor device 1, destruction thereof is caused by excess heat in the device, which is a function of the relationship of Esc=Isc×Tsc.

In the reference example where the insulating film 60 on the sides of the emitter regions 40 is not present, the potential of the emitter region 40 is less likely to increase while the saturation current is flowing, as compared to the semiconductor device 1. That is, in the reference example, the saturation current is less likely to flow only through the emitter region 40, and thus can also flow through the contact region 31 and into the emitter regions through the sides thereof exposed to the base region or contact region extending therebetween where no insulating film 60 is present, as compared to the semiconductor device 1.

Conversely, in the semiconductor device 1, the saturation current Icp passes into the emitter region 40 only from the collector region 22 side thereof, and is shielded from current flow through the sides thereof by the insulating film 60. Therefore, the saturation current Icp is more likely to flow through only the emitter region 40.

It is noted that, as another method for reducing the short-circuit current, there is a method in which the channel region is narrowly formed, even when the device is operating within is rating. However, this method increases the on-state resistance and the like of the device even within its rated operating range, resulting in greater power losses in the device.

As above, according to the first embodiment, the potential of the emitter region 40 increases, and the potential of the base region 30 in contact with the emitter region 40 is induced to increase by the increase of the potential of the emitter region. Thereby, the apparent potential of the gate electrode 50 falls. As a result, the width of the channel region is narrowed to reduce or restrict the flow of the saturation current. In this way, according to the first embodiment, a semiconductor device having high short-circuit withstanding capability is achieved.

### Second Embodiment

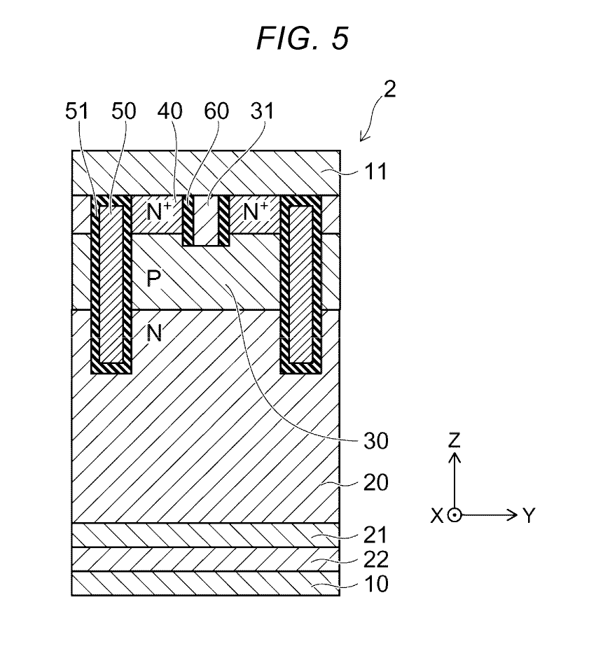

FIG. 5 is a schematic cross-sectional view illustrating a semiconductor device according to the second embodiment.

In the semiconductor device 2 of the second embodiment, the distance between the insulating film 60 and the collector electrode 10 is shorter than the distance between the emitter region 40 and the collector electrode 10. In other words, the bottom of the insulating film 60 extends further into the base region than does the bottom of emitter region 40.

In the semiconductor device 2, while the saturation current is flowing, the accumulation effect, i.e., the restricting of the saturation flow path to the emitter regions 40 when saturation current Icp is present is further increased by the amount of extension of the insulating film 60 toward the collector electrode 10, as compared to the semiconductor device 1. Accordingly, in the semiconductor device 2, the potential of the emitter region 40 further increases as compared to the semiconductor device 1. That is, according to the second embodiment, a semiconductor device having greater short-circuit withstand capability is achieved.

### Third Embodiment

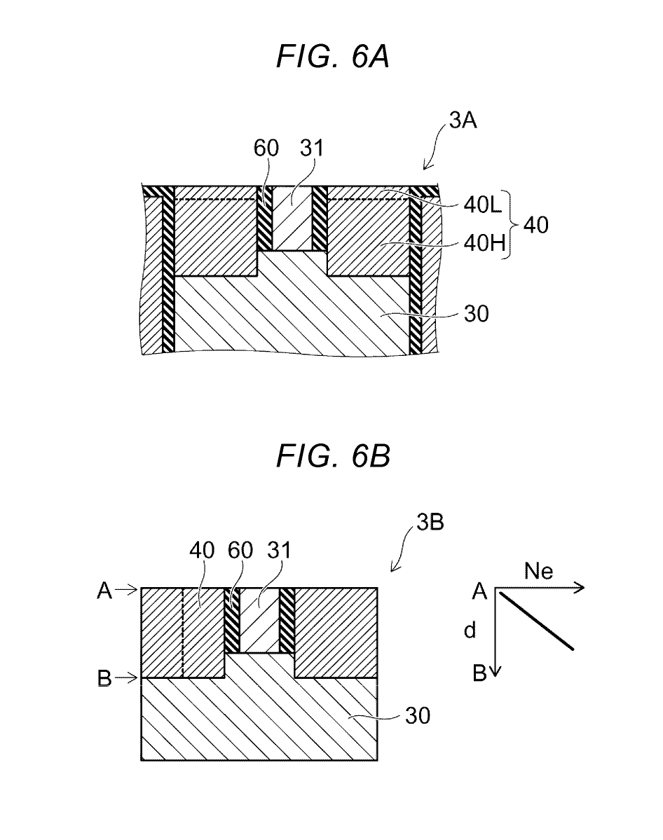

FIGS. 6A and 6B are schematic cross-sectional views illustrating semiconductor devices according to the third embodiment.

FIGS. 6A and 6B illustrate an enlarged view of the base region 30 and the emitter region 40.

In the semiconductor device 3A illustrated in FIG. 6A, the emitter region 40 includes a low dopant concentration region 40L and a high dopant concentration region 40H, wherein the low concentration region is disposed between the emitter electrode 11 and a high concentration region 40H, and between the insulating film 60 and the insulating 51 on the gate electrode 50. Here, the specific resistance of the low dopant concentration region 40L is greater than the specific resistance of the high dopant concentration region 40H.

In the semiconductor device 3B illustrated in FIG. 6B, the dopant concentration in the emitter region 40 is graded, i.e., it is lower at a position closer to the emitter electrode 11 than at a position closer to the collector electrode 10. For example, the dopant concentration of the emitter region 40 becomes lower from a position closest to the collector electrode 10 toward a position closest to the emitter electrode 11. That is, the specific resistance of the emitter region 40 gradually becomes lower from the position closest to the collector electrode 10 toward the position closest to the emitter electrode 11.

These structures also reduce the flow of the saturation current Icp in the emitter region 40. That is, the potential of the emitter region 40 is further increased during saturation current flow, and a semiconductor device having high short-circuit withstand capability is achieved.

### Fourth Embodiment

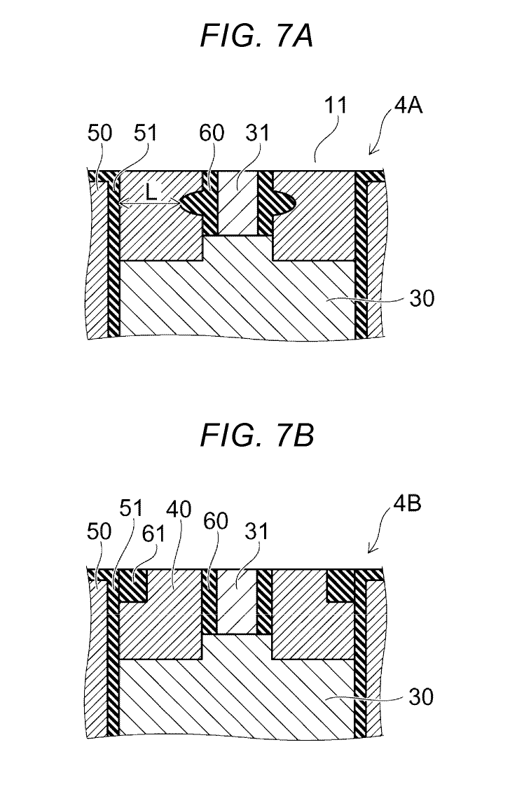

FIGS. 7A and 7B are schematic cross-sectional views illustrating semiconductor devices according to the fourth embodiment.

In the semiconductor device 4A illustrated in FIG. 7A, the distance between the gate electrode 50 and the insulating film 60 is variable along the depth of the insulating film 60 extending inwardly from the gate electrode 50. Specifically, a portion of the insulating film 60 protrudes toward the gate electrode 50. This creates a reduced cross section region in the emitter regions 40 where the distance between the emitter region 40 and the adjacent insulating film 51 on the adjacent gate electrode is reduced at a depth in the emitter region 40 spaced from the interface with the emitter electrode 11.

Meanwhile, in the semiconductor device 4B illustrated in FIG. 7B, an insulating film 61 (third insulating film) is provided between the gate electrode 50 and the insulating film 60, restricting the cross section of the emitter region 40 at the interface thereof with the emitter electrode 11.

These structures also reduce the flow of the saturation current Icp in the emitter region 40 by reducing the cross section of the emitter region 40 through which the saturation can flow, as compared to the cross section of the contact region of the emitter region 40 with the base region 30. As a result, the potential of the emitter region 40 may be further increased as compared to the semiconductor device 1 of the first embodiment, and a semiconductor device having high short-circuit withstanding capability is achieved.

### Fifth Embodiment

Further, in the emitter region 40, the quantity of dopant elements may be reduced in order to set a high specific resistance in the emitter region 40. This structure also reduces the flow of the saturation current Icp in the emitter region 40, so that the potential of the emitter region 40 is further increased as compared to the semiconductor device 1 when the saturation current flows. Further, by making the emitter region 40 a region including polysilicon, the potential of the emitter region 40 may be further increased when the saturation current flows therein. This is because polysilicon has a higher underlying resistivity compared to single crystal silicon. In this way, according to the fifth embodiment, a semiconductor device having further high short-circuit withstanding capability can be achieved.

In the above embodiments, the “on” in an expression “a portion A is provided on a portion B” may be used to mean a situation where the portion A is provided on the portion B with the portion A in contact with the portion B, as well as a situation where the portion A is provided above the portion B with the portion A not in contact with the portion B. Further, “a portion A is provided on a portion B” may be employed for a situation where the portion A and the portion B are inverted to locate the portion A beneath the portion B, as well as a situation where the portion A and the portion B are located side by side.

In the above, embodiments are described with reference to specific examples. However, embodiments are not limited the specific examples. That is, the specific examples modified with design changes given by those skilled in the art as appropriate are also included in the scope of embodiments, as far as the modified examples have the feature of embodiments. Each element and its arrangement, material, condition, shape, size and so forth of the aforementioned each specific example are not limited to what is illustrated as the examples, but may be changed as appropriate.

Further, each element in each aforementioned embodiment may be altered and combined, and the alterations and combinations thereof are also included in the scope of embodiments, as far as the combinations and alterations have the feature of embodiments. Besides, it should be understood that, within the spirit of embodiments, those skilled in the art will envision various altered examples and modified examples, and those altered examples and modified examples are also within the scope of embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first electrode;
a first semiconductor region of a first conductivity type;
a second semiconductor region of a second conductivity type provided on the first semiconductor region;
a third semiconductor region of the first conductivity type located between and contacting the second semiconductor region and the first electrode, the third semiconductor region having a dopant concentration higher than a dopant concentration of the first semiconductor region;
a second electrode, having a first insulating film thereover, being in contact, via the first insulating film, with the first semiconductor region, the second semiconductor region, and the third semiconductor region; and
a second insulating film, the third semiconductor region being interposed between the second insulating film and the third electrode.

2. The semiconductor device according to claim 1, further comprising a third electrode, wherein the first semiconductor region is located intermediate of the third electrode and the second semiconductor region.

3. The semiconductor device according to claim 1, wherein the distance between the second insulating film and the third electrode is greater than the distance between the third semiconductor region and the third electrode.

4. The semiconductor device according to claim 1, wherein a distance between the second insulating film and the third electrode is less than the distance between the third semiconductor region and the third electrode.

5. The semiconductor device according to claim 1, wherein
the third semiconductor region comprises:
a low dopant concentration region provided in a portion thereof; and
a higher dopant concentration region provided in a portion thereof area closer to the third electrode than a low dopant concentration region thereof.

6. The semiconductor device according to claim 1, wherein
the third semiconductor region has a dopant concentration thereof, at a position thereof closer to the first electrode than the third electrode, lower than a dopant concentration thereof at a position thereof closer to the third electrode.

7. The semiconductor device according to claim 1, wherein
the third semiconductor region is interposed between the second electrode and the second insulating film, and
a distance between the second electrode and the second insulating film varies along the length of the interface surface between the third semiconductor region and the second insulating film.

8. The semiconductor device according to claim 1, further comprising
a third insulating film extending between the second electrode and the second insulating film along a portion of the contact region between the second electrode and the second insulating film.

9. A solid state semiconductor device, comprising:
a first electrode;
a first doped region of a first conductivity type overlying the first electrode;
a second doped region of a first conductivity type overlying the first doped region;
a first and a second trench electrode extending along opposed sides of the second doped region, each trench electrode having an insulating film formed thereover;
a second electrode overlying the trench electrodes and second doped region;
a third doped region of a second conductivity type and a fourth doped region of a second conductivity type interposed between the second doped region and the second electrode, wherein the third doped region abuts the insulating film overlying the first trench electrode, and the fourth doped region abuts the insulating film overlying the second electrode;
a fifth doped region of the first conductivity type interposed between the second doped layer and the second electrode; and
a second insulating film interposed between the fifth doped region and the third doped region and between the fifth doped region and the fourth doped region.

10. The semiconductor device of claim 9, wherein a distance between the second insulating layer and the insulating layer on the trench electrode disposed on an opposed side of at least one of the third and fourth doped regions varies over the length of the second insulating layer extending inwardly of the device from the second electrode.

11. The semiconductor device of claim 9, wherein the dopant concentration of the dopant type of at least one of the third and fourth doped regions varies in the direction thereof extending between the first and second electrodes.

12. The semiconductor device of claim 9, further comprising a third insulating film extending only partially along the region of contact between the third and the fourth doped regions with the insulating film.

13. The semiconductor device of claim 9, wherein at least one of the third and the fourth doped regions includes a first sub-region of a first dopant concentration contacting the second electrode and a second sub-region of a second dopant concentration contacting the second doped region.

14. The semiconductor device of claim 9, further comprising a sixth doped region of the second conductivity type interposed between the first doped region and the second doped region.

15. The semiconductor device of claim 14, wherein the trench electrodes extend inwardly of the sixth doped region.

16. The semiconductor device of claim 9, wherein the second insulating film includes a portion thereof located closer to the first electrode than any portion of an adjacent third and fourth doped region.

17. The semiconductor device of claim 9, wherein the third and fourth doped regions include a portion thereof located closer to the first electrode than any portion of the adjacent second insulating film.

18. A method of increasing the withstand of a semiconductor device having a first electrode, comprising:
providing a first doped region of a first conductivity type overlying the first electrode;
providing a second doped region of a first conductivity type overlying the first doped region
providing a first and a second trench electrode, each trench electrode having an insulating film formed thereover, extending along the opposed sides of the second doped region;
providing a second electrode overlying the trench electrodes and second doped region;
providing a third doped region and a fourth doped region of a second conductivity type interposed between the second doped region and the second electrode, wherein the third doped region abuts the insulating film overlying the first trench electrode, and the fourth doped region abuts the insulating film overlying the second electrode; and
positioning a fifth doped region interposed between the doped base layer and the second electrode; and
positioning a second insulating film between the fifth doped contact and the fourth doped region and between the fifth doped region and the fourth doped emitter region.

19. The method of claim 18, further comprising grading the dopant concentration in the third and fourth doped regions in the direction thereof extending from the interface location thereof with the second electrode.

20. The method of claim 18, further comprising locating the extension distance of the second insulating film from the location of contact thereof with the second electrode further inwardly of the second doped region than the extent of the third and fourth doped regions from the second electrode inwardly of the base region.
